(19) United States
(12) Patent Application Publication
(10) Pub. No.: US 2025/0343048 A1
(43) Pub. Date: Nov. 6, 2025

(54) ETCHING METHOD

(71) Applicant: Resonac Corporation, Tokyo (JP)

(72) Inventor: Atsushi SUZUKI, Tokyo (JP)

(73) Assignee: Resonac Corporation, Tokyo (JP)

(21) Appl. No.: 18/839,152

(22) PCT Filed: Dec. 13, 2022
(86) PCT No.: PCT/JP2022/045918

§ 371 Date: Feb. 11, 2025

(30) Foreign Application Priority Data
Feb. 16, 2022 (JP) 2022-022023

(51) Int. Cl. H01L 21/3065; H01J 37/32

(52) U.S. Cl. CPC H01L 21/3065; H01J 37/3244; H01J 37/32724; H01J 2237/334

(57) ABSTRACT

An etching method including an etching step of setting the temperature of a member to be etched having an etching object containing silicon to 0° C. or less, bringing an etching gas containing an etching compound into contact with the member to be etched, and etching the etching object, the etching compound being a compound having at least one type of atom among a fluorine atom, a hydrogen atom, and an oxygen atom in the molecule. The etching gas contains or does not contain metal impurities having at least one type of metal. When the etching gas contains the metal impurities, the total concentration of all types of the contained metals is 4000 ppb by mass or less.

### TECHNICAL FIELD

The present invention relates to an etching method.

### BACKGROUND ART

When manufacturing semiconductor elements, wiring lines are formed on a wafer by plasma etching. As the miniaturization of the wiring lines has progressed, a demand for wiring lines having a line width of 20 nm or less has increased. Therefore, when minute particles having a diameter of 100 nm or less are generated and remain on the wafer in plasma etching, there is a risk that the minute particles short-circuit the wiring lines or become obstacles in the subsequent etching, deposition steps, or the like, resulting in the inability to form the wiring lines. As a result, regions where designed electrical characteristics are not obtained are generated in the wafer, leading to a decrease in the productivity of the semiconductor elements. Accordingly, it is preferable that particles are hardly generated in the plasma etching. As a plasma etching method in which particles are hardly generated, a high-temperature etching method, in which etching is performed at temperatures equal to or more than normal temperature, is known.

In the plasma etching used in the manufacture of the semiconductor elements, a low side etching rate has been required. More specifically, in etching of an opening part having a high aspect ratio, it is preferable that lateral etching of a layer to be etched (e.g., a silicon-containing layer) directly under a mask hardly occurs. In the high-temperature etching method, particles are hardly generated. However, it has not been able to be said that the high-temperature etching method has had a sufficiently low side etching rate. As a plasma etching method having a low side etching rate, a low-temperature etching method in which etching is performed at temperatures of 0° C. or less is known (see PTL 1, for example).

### CITATION LIST

### Patent Literature

PTL 1: JP 2019-153771 A

### SUMMARY OF INVENTION

### Technical Problem

However, the low-temperature etching method has had a low side etching rate, but has been likely to generate particles.

It is an object of the present invention to provide an etching method in which particles are hardly generated, even when the etching method is a low-temperature etching method that is supposed to be able to keep the side etching rate low.

### Solution to Problem

To achieve the above-described object, one aspect of the present invention is as described in [1] to [12] below.

[1] An etching method including: an etching step of setting the temperature of a member to be etched having an etching object containing silicon to 0° C. or less, bringing an etching gas containing an etching compound into contact with the member to be etched, and etching the etching object, the etching compound being a compound having at least one type of atom among a fluorine atom, a hydrogen atom, and an oxygen atom in the molecule, in which
the etching gas contains or does not contain metal impurities having at least one type of metal, and, when the etching gas contains the metal impurities, the total concentration of all types of the contained metals is 4000 ppb by mass or less.

[2] The etching method according to [1], in which the total concentration of all types of the contained metals is 10 ppb by mass or more and 4000 ppb by mass or less.

[3] The etching method according to [1] or [2], in which the metal impurities have at least one type among alkaline metal, alkaline earth metal, chromium, manganese, iron, cobalt, nickel, copper, zinc, aluminum, and tin.

[4] The etching method according to [3], in which the alkaline metal is at least one type among lithium, sodium, and potassium, and the alkaline earth metal is at least one type of magnesium and calcium.

[5] The etching method according to any one of [1] to [4], in which the concentration of each of all types of the contained metals is 1 ppb by mass or more.

[6] The etching method according to any one of [1] to [5], in which the etching compound is at least one type among a compound having a fluorine atom in the molecule and not having a hydrogen atom and an oxygen atom in the molecule, a compound having a hydrogen atom in the molecule and not having a fluorine atom and an oxygen atom in the molecule, a compound having an oxygen atom in the molecule and not having a fluorine atom and a hydrogen atom in the molecule, a compound having a fluorine atom and a hydrogen atom in the molecule and not having an oxygen atom in the molecule, a compound having a fluorine atom and an oxygen atom in the molecule and not having a hydrogen atom in the molecule, and a compound having a hydrogen atom and an oxygen atom in the molecule and not having a fluorine atom in the molecule.

[7] The etching method according to [6], in which the compound having a fluorine atom in the molecule and not having a hydrogen atom and an oxygen atom in the molecule is at least one type among sulfur hexafluoride, nitrogen trifluoride, chlorine trifluoride, iodine heptafluoride, bromine pentafluoride, phosphorus trifluoride, trifluoroiodomethane, fluorine gas, chain saturated perfluorocarbons having 1 or more and 3 or less carbon atoms, unsaturated perfluorocarbons having 2 or more and 6 or less carbon atoms, cyclic perfluorocarbons having 3 or more and 6 or less carbon atoms, and halons having 1 or more and 3 or less carbon atoms.

[8] The etching method according to [6], in which the compound having a hydrogen atom in the molecule and not having a fluorine atom and an oxygen atom in the molecule is at least one type among bromomethane, dibromomethane, hydrogen gas, hydrogen sulfide, hydrogen chloride, hydrogen bromide, ammonia, alkanes having 1 or more and 3 or less carbon atoms, alkenes having 2 or more and 4 or less carbon atoms, and cyclic alkanes having 3 or more and 6 or less carbon atoms.

[9] The etching method according to [6], in which the compound having an oxygen atom in the molecule and not having a fluorine atom and a hydrogen atom in the molecule is at least one type among oxygen gas, carbon monoxide, carbon dioxide, carbonyl sulfide, and sulfur dioxide.

[10] The etching method according to [6], in which the compound having a fluorine atom and a hydrogen atom in the molecule and not have an oxygen atom in the molecule is at least one type among chain saturated hydrofluorocarbons having 1 or more and 4 or less carbon atoms, unsaturated hydrofluorocarbons having 2 or more and 6 or less carbon atoms, and cyclic hydrofluorocarbons having 3 or more and 6 or less carbon atoms, and hydrogen fluoride.

[11] The etching method according to [6], in which the compound having a fluorine atom and an oxygen atom in the molecule and not having a hydrogen atom in the molecule is at least one type among carbonyl fluoride, oxygen difluoride, trifluoromethyl hypofluoride, perfluoroethers having 2 or more and 4 or less carbon atoms, and perfluoroketones having 3 or more and 5 or less carbon atoms.

[12] The etching method according to [6], in which the compound having a hydrogen atom and an oxygen atom in the molecule and not having a fluorine atom in the molecule is at least one type among water, alcohols having 1 or more and 3 or less carbon atoms, ethers having 2 or more and 4 or less carbon atoms, and ketones having 3 or more and 5 or less carbon atoms.

### Advantageous Effects of Invention

According to the present invention, even in the case of a low-temperature etching method that is supposed to be able to keep the side etching rate low, particles are hardly generated.

### BRIEF DESCRIPTION OF DRAWINGS

FIG. 1 is a schematic diagram of one example of an etching device for explaining one embodiment of an etching method according to the present invention.

### DESCRIPTION OF EMBODIMENTS

Hereinafter, one embodiment of the present invention is described. This embodiment describes one example of the present invention, and the present invention is not limited to this embodiment. This embodiment can be variously altered or improved, and such altered or improved aspects can also be included in the present invention.

An etching method according to this embodiment includes an etching step of setting the temperature of a member to be etched having an etching object containing silicon to 0° C. or less, bringing an etching gas containing an etching compound into contact with the member to be etched, and etching the etching object, the etching compound being a compound having at least one type of atom among a fluorine atom, a hydrogen atom, and an oxygen atom in the molecule. The etching gas contains or does not contain metal impurities having at least one type of metal, and, when the etching gas contains the metal impurities, the total concentration of all types of the contained metals is 4000 ppb by mass or less.

When the etching gas containing the above-described etching compound is brought into contact with the member to be etched, the etching object containing silicon and the above-described etching compound in the etching gas react with each other, and therefore the etching of the etching object progresses. In contrast thereto, a non-etching object, such as a mask, hardly reacts with the above-described etching compound, and therefore the etching of the non-etching object hardly progresses. Accordingly, the etching method according to this embodiment can selectively etch the etching object over the non-etching object (i.e., high etching selectivity is obtained).

The etching method according to this embodiment is a low-temperature etching method in which etching is performed at temperatures of 0° C. or less, and therefore etching can be performed at a lower side etching rate. Further, according to the etching method of this embodiment, the etching gas does not contain the metal impurities or, even when the etching gas contains the metal impurities, the amount is very small, and therefore particles are hardly generated in the etching.

Accordingly, the etching method according to this embodiment can be utilized for the manufacture of a semiconductor element. For example, when the etching method according to this embodiment is applied to a semiconductor substrate having a thin film containing a silicon compound and the thin film containing a silicon compound is etched, a semiconductor element can be manufactured. In the etching method according to this embodiment, particles, which cause a reduction in yield, are hardly generated, and therefore the productivity of the semiconductor element is high.

The number of the particles present on the surface of the member to be etched after the etching can be measured with a commercially available device. For example, the use of a Surfscan SP1 manufactured by KLA Tencor enables the detection of particles having a diameter of 50 nm or more. The number of the particles present on the surface of the member to be etched after the etching is preferably 0.5 particles/cm² or less, more preferably 0.1 particles/cm² or less, and still more preferably 0.05 particles/cm² or less.

The etching in the present invention refers to partially or entirely removing the etching object possessed by the member to be etched and processing the member to be etched into a specified shape (e.g., a three-dimensional shape) (e.g., processing a film-like etching object containing a silicon compound possessed by the member to be etched to have a predetermined film thickness). The “concentrations of metals” in the present invention are not the concentration of metal impurities but the concentrations of metals possessed by metal impurities. Further, the “metal” in the “concentrations of metals” in the present invention includes metal atoms and metal ions.

Hereinafter, the etching method according to this embodiment is described in more detail.

### [Etching Method]

For the etching method according to this embodiment, both plasma etching using a plasma or plasmaless etching using no plasma are usable. Examples of the plasma etching include reactive ion etching (RIE), inductively coupled plasma (ICP) etching, capacitively coupled plasma (CCP) etching, electron cyclotron resonance (ECR) plasma etching, and microwave plasma etching.

In the plasma etching, a plasma may be generated in a chamber where the member to be etched is placed or a plasma generating chamber and the chamber where the member to be etched is placed may be separated from each other (i.e., a remote plasma may be used). By etching using the remote plasma, the etching object containing silicon can be sometimes etched at a higher selectivity.

### [Etching Compound]

The etching compound contained in the etching gas is a compound that reacts with the etching object containing silicon to make etching of the etching object progress. The type of the etching compound is not particularly limited insofar as it is a compound having at least one type of atom among a fluorine atom, a hydrogen atom, and an oxygen atom in the molecule, and examples include the compounds below.

More specifically, examples of the etching compound include a compound having a fluorine atom in the molecule and not having a hydrogen atom and an oxygen atom in the molecule, a compound having a hydrogen atom in the molecule and not having a fluorine atom and an oxygen atom in the molecule, a compound having an oxygen atom in the molecule and not having a fluorine atom and a hydrogen atom in the molecule, a compound having a fluorine atom and a hydrogen atom in the molecule and not having an oxygen atom in the molecule, a compound having a fluorine atom and an oxygen atom in the molecule and not having a hydrogen atom in the molecule, a compound having a hydrogen atom and an oxygen atom in the molecule and not having a fluorine atom in the molecule, and a compound having a fluorine atom, a hydrogen atom, and an oxygen atom in the molecule.

Specific examples of the compound having a fluorine atom in the molecule and not having a hydrogen atom and an oxygen atom in the molecule include sulfur hexafluoride (SF₆), nitrogen trifluoride (NF₃), chlorine trifluoride (CIF₃), iodine heptafluoride (IF₇), bromine pentafluoride (BrF₅), phosphorus trifluoride (PF₃), trifluoroiodomethane (CF₃I), fluorine gas (F₂), chain saturated perfluorocarbons having 1 or more and 3 or less carbon atoms, unsaturated perfluorocarbons having 2 or more and 6 or less carbon atoms, cyclic perfluorocarbons having 3 or more and 6 or less carbon atoms, and halons having 1 or more and 3 or less carbon atoms.

Specific examples of the chain saturated perfluorocarbons having 1 or more and 3 or less carbon atoms include tetrafluoromethane (CF₄), hexafluoroethane (C₂F₆), and octafluoropropane (C₃F₈).

Specific examples of the unsaturated perfluorocarbons having 2 or more and 6 or less carbon atoms include tetrafluoroethylene (C₂F₄), hexafluoropropylene (C₃F₆), octafluoro-1-butene (C₄F₈), octafluoro-2-butene (C₄F₈), perfluoroisobutene (C₄F₈), hexafluorobutadiene (C₄F₆), hexafluoro-1-butyne (C₄F₆), hexafluoro-2-butyne (C₄F₆), decafluoro-1-pentene (C₅F₁₀), decafluoro-2-pentene (C₅F₁₀), perfluoro-2-methyl-2-butene (C₅F₁₀), octafluoro-1,4-pentadiene (C₅F₈), octafluoro-2,3-pentadiene (C₅F₈), octafluoro-1,3-pentadiene (C₅F₈), octafluoro-2-pentyne (C₅F₈), pentafluoro-3-trifluoromethyl-1-butyne (C₅F₈), decafluoro-1-hexene (C₆F₁₂), decafluoro-2-hexene (C₆F₁₂), decafluoro-3-hexene (C₆F₁₂), perfluoro-4-methyl-2-pentene (C₆F₁₂), perfluoro (2-methyl-2-pentene) (C₆F₁₂), perfluoro (2,3-dimethyl-2-butene) (C₆F₁₂), decafluoro-1,5-hexadiene (C₆F₁₀), decafluoro-2,4-hexadiene (C₆F₁₀), decafluoro-1,3-hexadiene (C₆F₁₀), decafluoro-1,4-hexadiene (C₆F₁₀), decafluoro-1-hexyne (C₆F₁₀), decafluoro-2-hexyne (C₆F₁₀), and decafluoro-3-hexyne (C₆F₁₀).

Specific example of the cyclic perfluorocarbons having 3 or more and 6 or less carbon atoms include hexafluorocyclopropane (C₃F₆), octafluorocyclobutane (C₄F₈), perfluorocyclobutene (C₄F₆), perfluorocyclopentene (C₅F₈), perfluorocyclopentane (C₅F₁₀), perfluoromethyl cyclobutane (C₅F₁₀), hexafluorobenzene (C₆F₆), perfluorocyclohexane (C₆F₁₂), perfluoromethyl cyclopentane (C₆F₁₂), perfluoro-1,2-dimethyl cyclobutane (C₆F₁₂), perfluoro-2,4-dimethyl cyclobutane (C₆F₁₂), perfluoro-3,4-dimethyl cyclobutane (C₆F₁₂), and perfluoro-4,4-dimethyl cyclobutane (C₆F₁₂).

Specific example of the halons having 1 or more and 3 or less carbon atoms include bromotrifluoromethane (CBrF₃), dibromodifluoromethane (CBr₂F₂), tribromofluoromethane (CBr₃F), bromopentafluoroethane (C₂BrF₅), dibromotetrafluoroethane (C₂Br₂F₄), tribromotrifluoroethane (C₂Br₃F₃), tetrabromodifluoroethane (C₂Br₄F₂), pentabromofluoroethane (C₂Br₅F), bromotrifluoroethylene (C₂BrF₃), dibromodifluoroethylene (C₂Br₂F₂), tribromofluoroethylene (C₂Br₃F), bromoheptafluoropropane (C₃BrF₇), dibromohexafluoropropane (C₃Br₂F₆), tribromopentafluoropropane (C₃Br₃F₅), tetrabromotetrafluoropropane (C₃Br₄F₄), pentabromotrifluoropropane (C₃Br₅F₃), hexabromodifluoropropane (C₃Br₆F₂), heptabromofluoropropane (C₃Br₇F), bromopentafluoropropene (C₃BrF₅), dibromotetrafluoropropene (C₃Br₂F₄), tribromotrifluoropropene (C₃Br₃F₃), tetrabromodifluoropropene (C₃Br₄F₂), pentabromofluoropropene (C₃Br₅F), bromopentafluorocyclopropane (C₃BrF₅), dibromotetrafluorocyclopropane (C₃Br₂F₄), tribromotrifluorocyclopropane (C₃Br₃F₃), tetrabromodifluorocyclopropane (C₃Br₄F₂), pentabromofluorocyclopropane (C₃Br₅F), bromotrifluorocyclopropene (C₃BrF₃), dibromodifluorocyclopropene (C₃Br₂F₂), and tribromofluorocyclopropene (C₃Br₃F).

In general, the halons refer to those having bromine atoms among halogenated hydrocarbons in which some or all of hydrogen atoms possessed by the hydrocarbons are substituted with halogen atoms, while, in the present invention, the halons refer to those having bromine atoms and fluorine atoms among halogenated hydrocarbons in which all of hydrogen atoms possessed by the hydrocarbons are substituted with halogen atoms.

Specific examples of the compound having a hydrogen atom in the molecule and not having a fluorine atom and an oxygen atom in the molecule include bromomethane (CH₃Br), dibromomethane (CH₂Br₂), hydrogen gas (H₂), hydrogen sulfide (H₂S), hydrogen chloride (HCl), hydrogen bromide (HBr), ammonia (NH3), alkanes having 1 or more and 3 or less carbon atoms, alkenes having 2 or more and 4 or less carbon atoms, and cyclic alkanes having 3 or more and 6 or less carbon atoms.

Specific examples of the alkanes having 1 or more and 3 or less carbon atoms include methane (CH₄), ethane (C₂H₆), and propane (C₃H₈).

Specific examples of the alkenes having 2 or more and 4 or less carbon atoms include ethylene (C₂H₄), propylene (C₃H₆), 1-butene (C₄H₈), 2-butene (C₄H₈), and isobutene (C₄H₈).

Specific examples of the cyclic alkanes having 3 or more and 6 or less carbon atoms include cyclopropane (C₃H₆), cyclobutane (C₄H₈), cyclopentane (C₅H₁₀), and cyclohexane (C₆H₁₂).

The alkanes, alkenes, and cyclic alkanes above refer to those not having a fluorine atom and an oxygen atom in the molecules in the present invention.

Specific examples of the compound having an oxygen atom in the molecule and not having a fluorine atom and a hydrogen atom in the molecule include oxygen gas (O₂), ozone (O₃), carbon monoxide (CO), carbon dioxide (CO₂), carbonyl sulfide (COS), and sulfur dioxide (SO₂).

Specific examples of the compound having a fluorine atom and a hydrogen atom in the molecule and not having an oxygen atom in the molecule include chain saturated hydrofluorocarbons having 1 or more and 4 or less carbon atoms, unsaturated hydrofluorocarbons having 2 or more and 6 or less carbon atoms, cyclic hydrofluorocarbons having 3 or more and 6 or less carbon atoms, and hydrogen fluoride (HF).

Specific examples of the chain saturated hydrofluorocarbons having 1 or more and 4 or less carbon atoms include fluoromethane (CH₃F), difluoromethane (CH₂F₂), trifluoromethane (CHF₃), fluoroethane (C₂H₅F), difluoroethane (C₂H₄F₂), trifluoroethane (C₂H₃F₃), tetrafluoroethane (C₂H₂F₄), pentafluoroethane (C₂HF₅), fluoropropane (C₃H₇F), difluoropropane (C₃H₆F₂), trifluoropropane (C₃H₅F₃), tetrafluoropropane (C₃H₄F₄), pentafluoropropane (C₃H₃F₅), hexafluoropropane (C₃H₂F₆), heptafluoropropane (C₃HF₇), fluorobutane (C₄H₉F), difluorobutane (C₄H₈F₂), trifluorobutane (C₄H₇F₃), tetrafluorobutane (C₄H₆F₄), pentafluorobutane (C₄H₅F₅), hexafluorobutane (C₄H₄F₆), heptafluorobutane (C₄H₃F₇), octafluorobutane (C₄H₂F₈), nanofluorobutane (C₄HF₉), fluoromethyl propane (C₄H₉F), difluoromethyl propane (C₄H₈F₂), trifluoromethyl propane (C₄H₇F₃), tetrafluoromethyl propane (C₄H₆F₄), pentafluoromethyl propane (C₄H₅F₅), hexafluoromethyl propane (C₄H₄F₆), heptafluoromethyl propane (C₄H₃F₇), octafluoromethyl propane (C₄H₂F₈), and nanofluoromethyl propane (C₄HF₉).

Specific examples of the unsaturated hydrofluorocarbons having 2 or more and 6 or less carbon atoms include 2,3,3,3-tetrafluoropropene (C₃H₂F₄), 1,3,3,3-tetrafluoropropene (C₃H₂F₄), cis-1,1,1,4,4,4 hexafluoro-2-butene (C₄H₂F₆), and trans-1,1,1,4,4,4-hexafluoro-2-butene (C₄H₂F₆).

Specific example of the cyclic hydrofluorocarbons having 3 or more and 6 or less carbon atoms include fluorocyclopropane (C₃H₅F), difluorocyclopropane (C₃H₄F₂), trifluorocyclopropane (C₃H₃F₃), tetrafluorocyclopropane (C₃H₂F₄), pentafluorocyclopropane (C₃HF₅), fluorocyclobutane (C₄H₇F), difluorocyclobutane (C₄H₆F₂), trifluorocyclobutane (C₄H₅F₃), tetrafluorocyclobutane (C₄H₄F₄), pentafluorocyclobutane (C₄H₃F₅), hexafluorocyclobutane (C₄H₂F₆), heptafluorocyclobutane (C₄HF₇), fluoromethyl cyclopropane (C₄H₇F), difluoromethyl cyclopropane (C₄H₆F₂), trifluoromethyl cyclopropane (C₄H₅F₃), tetrafluoromethyl cyclopropane (C₄H₄F₄), pentafluoromethyl cyclopropane (C₄H₃F₅), hexafluoromethyl cyclopropane (C₄H₂F₆), heptafluoromethyl cyclopropane (C₄HF₇), fluorocyclopentane (C₅H₉F), difluorocyclopentane (C₅H₈F₂), trifluorocyclopentane (C₅H₇F₃), tetrafluorocyclopentane (C₅H₆F₄), pentafluorocyclopentane (C₅H₅F₅), hexafluorocyclopentane (C₅H₄F₆), heptafluorocyclopentane (C₅H₃F₇), octafluorocyclopentane (C₅H₂F₈), nanofluorocyclopentane (C₅HF₉), fluoromethyl cyclobutane (C₅H₉F), difluoromethyl cyclobutane (C₅H₈F₂), trifluoromethyl cyclobutane (C₅H₇F₃), tetrafluoromethyl cyclobutane (C₅H₆F₄), pentafluoromethyl cyclobutane (C₅H₅F₅), hexafluoromethyl cyclobutane (C₅H₄F₆), heptafluoromethyl cyclobutane (C₅H₃F₇), octafluoromethyl cyclobutane (C₅H₂F₈), nanofluoromethyl cyclobutane (C₅HF₉), fluorodimethyl cyclopropane (CH₉F), difluorodimethyl cyclopropane (C₅H₈F₂), trifluorodimethyl cyclopropane (C₅H₇F₃), tetrafluorodimethyl cyclopropane (C₅H₆F₄), pentafluorodimethyl cyclopropane (C₅H₅F₅), hexafluorodimethyl cyclopropane (C₅H₄F₆), heptafluorodimethyl cyclopropane (C₅H₃F₇), octafluorodimethyl cyclopropane (C₅H₂F₈), nanofluorodimethyl cyclopropane (C₅HF₉), fluoroethyl cyclopropane (C₅HgF), difluoroethyl cyclopropane (C₅H₈F₂), trifluoroethyl cyclopropane (C₅H₇F₃), tetrafluoroethyl cyclopropane (C₅H₆F₄), pentafluoroethyl cyclopropane (C₅H₅F₅), hexafluoroethyl cyclopropane (C₅H₄F₆), heptafluoroethyl cyclopropane (C₅H₃F₇), octafluoroethyl cyclopropane (C₅H₂F₈), nanofluoroethyl cyclopropane (C₅HF₉), fluorocyclohexane (C₆H₁₁F), difluorocyclohexane (C₆H₁₀F₂), trifluorocyclohexane (C₆H₉F₃), tetrafluorocyclohexane (C₆H₈F₄), pentafluorocyclohexane (C₆H₇F₅), hexafluorocyclohexane (C₆H₆F₆), heptafluorocyclohexane (C₆H₅F₇), octafluorocyclohexane (C₆H₄F₈), nanofluorocyclohexane (C₆H₃F₉), decafluorocyclohexane (C₆H₂F₁₀), and undecafluorocyclohexane (C₆HF₁₁).

In the present invention, the hydrofluorocarbons refer to compounds in which some of hydrogen atoms possessed by the hydrocarbons are substituted with fluorine atoms.

Specific examples of the compound having a fluorine atom and an oxygen atom in the molecule and not having a hydrogen atom in the molecule include carbonyl fluoride (COF₂), oxygen difluoride (OF₂), trifluoromethyl hypofluoride (CF₃OF), perfluoroethers having 2 or more and 4 or less carbon atoms, and perfluoroketones having 3 or more and 5 or less carbon atoms.

Specific examples of the perfluoroethers having 2 or more and 4 or less carbon atoms include perfluorodimethyl ether (CF₃OCF₃), perfluoromethyl ethyl ether (CF₃OC₂F₅), perfluorodiethyl ether (C₂F₅OC₂F₅), and perfluoromethyl propyl ether (CF₃OC₃F₇).

Specific examples of the perfluoroketones having 3 or more and 5 or less carbon atoms include perfluoroacetone (CF₃COCF₃), perfluorobutanone (CF₃COC₂F₅), and perfluoropentanone (CF₃COC₃F₇, C₂F₅COC₂F₅).

In the present invention, the perfluoroethers refer to compounds in which all of hydrogen atoms of hydrocarbon groups possessed by the ethers are substituted with a fluorine atom, and the perfluoroketones refer to compounds in which all of hydrogen atoms of hydrocarbon groups possessed by the ketones are substituted with a fluorine atom.

Specific examples of the compound having a hydrogen atom and an oxygen atom in the molecule and not having a fluorine atom in the molecule include water (H₂O), alcohols having 1 or more and 3 or less carbon atoms, ethers having 2 or more and 4 or less carbon atoms, and ketones having 3 or more and 5 or less carbon atoms.

Specific examples of the alcohols having 1 or more and 3 or less carbon atoms include methanol (CH₃OH), ethanol (C₂H₅OH), propanol (C₃H₇OH), and isopropanol

Specific examples of the ethers having 2 or more and 4 or less carbon atoms include dimethyl ether (CH₃OCH₃), diethyl ether (C₂H₅OC₂H₅), methyl ethyl ether (CH₃OC₂H₅), and methyl propyl ether (CH₃OC₃H₇).

Specific examples of the ketones having 3 or more and 5 or less carbon atoms include acetone (CH₃COCH₃), butanone (CH₃COC₂H₅), and pentanone (CH₃COC₃H₇, C₂H₅COC₂H₅).

Specific examples of the compound having a fluorine atom, a hydrogen atom, and an oxygen atom in the molecule include hydrofluoroethers having 2 or more and 4 or less carbon atoms, fluoroalcohols having 2 or more and 4 or less carbon atoms, and hydrofluoroketones having 3 or more and 5 or less carbon atoms.

Specific examples of the hydrofluoroethers having 2 or more and 4 or less carbon atoms include pentafluorodimethyl ether (CHF₂OCF₃), tetrafluorodimethyl ether (CHF₂OCHF₂, CH₂FOCF₃), trifluorodimethyl ether (CH₃OCF₃, CH₂FOCHF₂), difluorodimethyl ether (CH₃OCHF₂, CH₂FOCH₂F), fluorodimethyl ether (CH₃OCH₂F), difluoromethyl pentafluoroethyl ether (CHF₂OC₂F₅), trifluoromethyl tetrafluoroethyl ether (CF₃OC₂HF₄), fluoromethyl pentafluoroethyl ether (CH₂FOC₂F₅), difluoromethyl tetrafluoroethyl ether (CHF₂OC₂HF₄), trifluoromethyl trifluoroethyl ether (CF₃OC₂H₂F₃), methyl pentafluoroethyl ether (CH₃OC₂F₅), fluoromethyl tetrafluoroethyl ether (CH₂FOC₂HF₄), difluoromethyl trifluoroethyl ether (CHF₂OC₂H₂F₃), trifluoromethyl difluoroethyl ether (CF₃OC₂H₃F₂), methyl tetrafluoroethyl ether (CH₃OC₂HF₄), fluoromethyl trifluoroethyl ether (CH₂FOC₂H₂F₃), difluoromethyl difluoroethyl ether (CHF₂OC₂H₃F₂), trifluoromethyl fluoroethyl ether (CF₃OC₂H₄F), methyl trifluoroethyl ether (CH₃OC₂H₂F₃), fluoromethyl difluoroethyl ether (CH₂FOC₂H₃F₂), difluoromethyl fluoroethyl ether (CHF₂OC₂H₄F), trifluoromethyl ethyl ether (CF₃OC₂H₅), methyl difluoroethyl ether (CH₃OC₂H₃F₂), fluoromethyl fluoroethyl ether (CH₂FOC₂H₄F), difluoroethyl ether (CHF₂OC₂H₅), methyl fluoroethyl ether (CH₃OC₂H₄F), fluoromethyl ethyl ether (CH₂FOC₂H₅), tetrafluoroethyl pentafluoroethyl ether (C₂HF₄OC₂F₅), bistetrafluoroethyl ether (C₂HF₄OC₂HF₄), pentafluoroethyl trifluoroethyl ether (C₂F₅OC₂H₂F₃), pentafluoroethyl difluoroethyl ether (C₂F₅OC₂H₃F₂), tetrafluoroethyl trifluoroethyl ether (C₂HF₄OC₂H₂F₃), pentafluoroethyl fluoroethyl ether (C₂F₅OC₂H₄F), tetrafluoroethyl difluoroethyl ether (C₂HF₄OC₂H₃F₂), bistrifluoroethyl ether (C₂H₂F₃OC₂H₂F₃), ethyl pentafluoroethyl ether (C₂H₅OC₂F₅), fluoroethyl tetrafluoroethyl ether (C₂H₄FOC₂HF₄), difluoroethyl trifluoroethyl ether (C₂H₃F₂OC₂H₂F₃), ethyl tetrafluoroethyl ether (C₂H₅OC₂HF₄), fluoroethyl trifluoroethyl ether (C₂H₄FOC₂H₂F₃), bisdifluoroethyl ether (C₂H₃F₂OC₂H₃F₂), ethyl difluoroethyl ether (C₂H₅OC₂H₃F₂), bisfluoroethyl ether (C₂H₄FOC₂H₄F), ethyl fluoroethyl ether (C₂H₅OC₂H₄F), difluoromethyl heptafluoropropyl ether (CHF₂OC₃F₇), trifluoromethyl hexafluoropropyl ether (CF₃OC₃HF₆), fluoromethyl heptafluoropropyl ether (CH₂FOC₃F₇), difluoromethyl hexafluoropropyl ether (CHF₂OCHF₆), trifluoromethyl pentafluoropropyl ether (CF₃OC₃H₂F₅), methyl heptafluoropropyl ether (CH₃OC₃F₇), fluoromethyl hexafluoropropyl ether (CH₂FOC₃HF₆), difluoromethyl pentafluoropropyl ether (CHF₂OC₃H₂F₅), trifluoromethyl tetrafluoropropyl ether (CF₃OC₃H₃F₄), methyl hexafluoropropyl ether (CH₃OCHF₆), fluoromethyl pentafluoropropyl ether (CH₂FOC₃H₂F₅), difluoromethyl tetrafluoropropyl ether (CHF₂OC₃H₃F₄), trifluoromethyl trifluoropropyl ether (CF₃OC₃H₄F₃), methyl pentafluoropropyl ether (CH₃OC₃H₂F₅), fluoromethyl tetrafluoropropyl ether (CH₂FOC₃H₃F₄), difluoromethyl trifluoropropyl ether (CHF₂OC₃H₄F₃), trifluoromethyl difluoropropyl ether (CF₃OC₃H₅F₂), methyl tetrafluoropropyl ether (CH₃OC₃H₃F₄), fluoromethyl trifluoropropyl ether (CH₂FOC₃H₄F₃), difluoromethyl difluoropropyl ether (CHF₂OC₃H₅F₂), trifluoromethyl fluoropropyl ether (CF₃OC₃H₆F), methyl trifluoropropyl ether (CH₃OC₃H₄F₃), fluoromethyl difluoropropyl ether (CH₂FOC₃H₂F₅), difluoromethyl fluoropropyl ether (CHF₂OC₃H₆F), trifluoromethyl propyl ether (CF₃OC₃H₇), methyl difluoropropyl ether (CH₃OC₃H₅F₂), fluoromethyl fluoropropyl ether (CH₂FOC₃H₆F), difluoromethyl propyl ether (CHF₂OC₃H₇), methyl fluoropropyl ether (CH₃OC₃H₆F), and fluoromethyl propyl ether (CH₂FOC₃H₇).

Specific examples of the fluoroalcohols having 2 or more and 4 or less carbon atoms include trifluoroethanol (CF₃CH₂OH), hexafluoro-2-propanol (CF₃CH(OH)CF₃), pentafluoropropanol (C₂F₅CH₂OH), pentafluoro-2-propanol (CF₃CH(OH)CHF₂), tetrafluoropropanol (C₂HF₄CH₂OH), tetrafluoro-2-propanol (CF₃CH(OH)CH₂F, CHF₂CH(OH)CHF₂), trifluoropropanol (C₂H₂F₃CH₂OH), trifluoro-2-propanol (CF₃CH(OH)CH₃, CHF₂CH(OH)CH₂F), difluoropropanol (C₂H₃F₂CH₂OH), difluoro-2-propanol (CHF₂CH(OH)CH₃, CH₂FCH(OH)CH₂F), fluoropropanol (C₂H₄FCH₂OH), fluoro-2-propanol (CH₂FCH(OH)CH₃), and perfluoro-t-butanol (CF₃C(CF₃)(OH)CF₃).

Specific examples of the hydrofluoroketones having 3 or more and 5 or less carbon atoms include pentafluoroacetone (CF₃COCHF₂), tetrafluoroacetone (CF₃COCH₂F, CHF₂COCHF₂), trifluoroacetone (CF₃COCH₃, CHF₂COCH₂F), difluoroacetone (CHF₂COCH₃, CH₂FCOCH₂F), heptafluorobutanone (C₂F₅COCHF₂, C₂HF₄COCF₃), hexafluorobutanone (C₂FSCOCH₂F, C₂HF₄COCHF₂, C₂H₂F₃COCH₃), pentafluorobutanone (C₂F₅COCH₃, C₂HF₄COCH₂F, C₂H₂F₃COCHF₂, C₂H₃F₂COCF₃), tetrafluorobutanone (C₂HF₄COCH₃, C₂H₂F₃COCH₂F, C₂H₃F₂COCHF₂, C₂H₄FCOCF₃), trifluorobutanone (C₂H₂F₃COCH₃, C₂H₃F₂COCH₂F, C₂H₄FCOCHF₂, C₂H₅COCF₃), difluorobutanone (C₂H₃F₂COCH₃, C₂H₄FCOCH₂F, C₂H₅COCHF₂), fluorobutanone (C₂H₄FCOCH₃, C₂HSCOCH₂F), nonafluoro-3-pentanone (C₂F₅COC₂HF₄), octafluoro-3-pentanone (C₂F₅COC₂H₂F₃, C₂HF₄COC₂HF₄), heptafluoro-3-pentanone (C₂F₅COC₂H₃F₂, C₂HF₄COC₂H₂F₃), hexafluoro-3-pentanone (C₂F₅COC₂H₄F, C₂HF₄COC₂H₃F₂, C₂H₂F₃COC₂H₂F₃), pentafluoro-3-pentanone (C₂F₅COC₂H₅, C₂HF₄COC₂H₄F, C₂H₂F₃COC₂H₃F₂), tetrafluoro-3-pentanone (C₂HF₄COC₂H₅, C₂H₂F₃COC₂H₄F, C₂H₃F₂COC₂H₃F₂), trifluoro-3-pentanone (C₂H₂F₃COC₂H₅, C₂H₃F₂COC₂H₄F), difluoro-3-pentanone (C₂H₃F₂COC₂H₅, C₂H₄FCOC₂H₄F), fluoro-3-pentanone (C₂H₄FCOC₂H₅), nanofluoro-2-pentanone (CHF₂COC₃F₇, CF₃COC₃HF₆), octafluoro-2-pentanone (CH₂FCOC₃F₇, CHF₂COC₃HF₆, CF₃COC₃H₂F₅), heptafluoro-2-pentanone (CH₃COC₃F₇, CH₂FCOC₃HF₆, CHF₂COC₃H₂F₅, CF₃COC₃H₃F₄), hexafluoro-2-pentanone (CH₃COC₃HF₆, CH₂FCOC₃H₂F₅, CHF₂COC₃H₃F₄, CF₃COC₃H₄F₃), pentafluoro-2-pentanone (CH₃COC₃H₂F₅, CH₂FCOC₃H₃F₄, CHF₂COC₃H₄F₃, CF₃COC₃H₅F₂), tetrafluoro-2-pentanone (CH₃COC₃H₃F₄, CH₂FCOC₃H₄F₃, CHF₂COC₃H₅F₂, CF₃COC₃H₆F), trifluoro-2-pentanone (CH₃COC₃H₄F₃, CH₂FCOC₃H₅F₂, CHF₂COC₃H₆F, CF₃COC₃H₇), difluoro-2-pentanone (CH₃COC₃H₅F₂, CH₂FCOC₃H₆F, CHF₂COC₃H₇), and fluoro-2-pentanone (CH₃COC₃H₆F, CH₂FCOC₃H₇).

These etching compounds may be used alone or in combination of two or more types thereof.

### [Etching Gas]

The etching gas is gas containing the above-described etching compounds. The etching gas may be gas containing only the above-described etching compounds or may be mixed gas containing the above-described etching compounds and dilution gas. The etching gas may also be mixed gas containing the above-described etching compounds, dilution gas, and additive gas.

As the dilution gas, at least one type selected from nitrogen gas (N₂), helium (He), neon (Ne), argon (Ar), krypton (Kr), and xenon (Xe) is usable.

The content of the dilution gas is preferably 90% by volume or less and more preferably 50% by volume or less based on the total amount of the etching gas. The content of the dilution gas is preferably 10% by volume or more based on the total amount of the etching gas.

From the viewpoint of increasing the etching rate, the content of the etching compound in the etching gas is preferably 5% by volume or more and more preferably 10% by volume or more based on the total amount of the etching gas. From the viewpoint of reducing the usage amount of the etching compound, the content of the etching compound is preferably 90% by volume or less and more preferably 80% by volume or less based on the total amount of the etching gas.

The etching gas can be obtained by mixing a plurality of components (etching compound, dilution gas, and the like) constituting the etching gas. The mixing of the plurality of components may be performed either inside or outside a chamber. More specifically, the plurality of components constituting the etching gas each may be independently introduced into a chamber and mixed in the chamber or the plurality of components constituting the etching gas may be mixed to obtain the etching gas, and the obtained etching gas may be introduced into the chamber.

### [Metal Impurities]

The etching gas contains or does not contain metal impurities having at least one type of metal. When the metal impurities are contained, the total concentration of all types of metals contained in the etching gas is as low as 4000 ppb by mass or less, and therefore particles are hardly generated in etching as described above. The total concentration of all types of the contained metals is preferably 1000 ppb by mass or less and more preferably 100 ppb by mass or less.

When water is generated in etching, the water condenses on the surface of a member to be etched, which has reached 0° C. or less. When the compound having a fluorine atom in the molecule is used as the etching compound, the contact of a hydrogen fluoride radical generated in etching with the water on the surface of the member to be etched generates hydrofluoric acid, and therefore etching by a chemical reaction is promoted, increasing the etching rate.

However, when the metal impurities are contained in the etching gas, there is a risk that particles are generated due to metal fluoride generated by a reaction between the metal impurities with hydrofluoric acid. The metal fluoride is chemically stable and has low volatility, and therefore is difficult to be removed by a dry process. Therefore, the metal fluoride can become an obstacle in the subsequent etching, deposition step, or the like. Therefore, the amount of the metal impurities contained in the etching gas is preferably smaller, and the total concentration of all types of metals contained in the etching gas needs to be 4000 ppb by mass or less.

The total concentration of all types of metals contained in the etching gas may be 10 ppb by mass or more. The concentration of each of all types of metals contained in the etching gas may be 1 ppb by mass or more.

The concentrations of the metals in the etching gas can be quantified with an inductively coupled plasma mass spectrometer (ICP-MS). Herein, not containing the metal impurities refers to a case where the quantification with the inductively coupled plasma mass spectrometer is impossible.

Metals possessed by the metal impurities include alkaline metals, alkaline earth metals, and metals belonging to Groups 3 to 14 of the periodic table (e.g., transition metals).

Examples of the alkaline metals include lithium (Li), sodium (Na), potassium (K), rubidium (Rb), cesium (Cs), and francium (Fr). Examples of the alkaline earth metals include beryllium (Be), magnesium (Mg), calcium (Ca), strontium (Sr), barium (Ba), and radium (Ra).

Examples of the metals belonging to Groups 3 to 14 of the periodic table include chromium (Cr), manganese (Mn), iron (Fe), cobalt (Co), nickel (Ni), copper (Cu), zinc (Zn), aluminum (Al), and tin (Sn).

The metals possessed by the metal impurities may be one type or two or more types of these metals.

The above-described metal impurities are sometimes contained in the etching gas as a metal simple substance, a metal compound, metal halide, or a metal complex. The forms of the metal impurities in the etching gas include fine particles, liquid droplets, gas, and the like. The above-described metal impurities are considered to be mixed into the etching gas through raw materials, a reactor, a purification device, a filling container, or the like used in the synthesis of the above-described etching compounds.

Methods for removing the above-described metal impurities from the above-described etching compounds include, for example, a method including passing the above-described etching compounds through a filter, a method including bringing the above-described etching compounds into contact with an adsorbent, or a method including separating the above-described etching compounds by distillation. Then, specifically, the above-described etching compounds are sealed in a stainless steel cylinder and the temperature is kept at a temperature equal to or less than the boiling points of the etching compounds under the internal pressure of the cylinder, for example, (e.g., in the case of tetrafluoromethane, the temperature is kept at −125° C. under the internal pressure of the cylinder slightly higher than 1 atm), and a gas phase part is extracted using the method described in Examples described later or the like, and thus the etching gas with a reduced metal concentration can be obtained. The etching gas is preferably used for etching after the total concentration of the metals contained in the etching gas is reduced to 4000 ppb by mass or less by such a step of removing the metal impurities.

### [Temperature Condition of Etching Step]

The etching method according to this embodiment is a low-temperature etching method, and therefore etching is performed after the temperature of the member to be etched is set to 0° C. or less. The temperature of the member to be etched is preferably set to −20° C. or less and more preferably set to −40° C. or less. When etching is performed after the temperature of the member to be etched is set within the range above, the etching can be performed at a lower side etching rate.

Herein, the temperature of the temperature condition is the temperature of the member to be etched, but the temperature of a stage, which is installed in a chamber of an etching device and supports the member to be etched, is also usable.

A bias power constituting a potential difference between a plasma generated when etching is performed and the member to be etched can be selected from 0 to 10000 W according to a desired etching shape. When etching is selectively performed, the bias power is preferably about 0 to 1000 W.

### [Pressure Condition of Etching Step]

The pressure condition of the etching step in the etching method according to this embodiment is not particularly limited, and is preferably set to 10 Pa or less and more preferably set to 5 Pa or less. When the pressure condition is within the range above, a plasma is likely to be stably generated. The pressure condition of the etching step is preferably 0.05 Pa or more. When the pressure condition is within the range above, a large number of ionization ions are generated and a sufficient plasma density is likely to be obtained.

The flow rate of the etching gas may be set as appropriate such that the pressure in a chamber is kept constant according to the volume of the chamber or the capacity of an exhaust facility of reducing the pressure in the chamber.

### [Member to be Etched]

The member to be etched that is etched by the etching method according to this embodiment has the etching object that is an object to be etched and may further contain a non-etching object that is not an object to be etched.

When the member to be etched has the etching object and the non-etching object, the member to be etched may be a member having a portion formed of the etching object and a portion formed of the non-etching object or may be a member formed of a mixture of the etching object and the non-etching object. The member to be etched may have things other than the etching object and the non-etching object.

The shape of the member to be etched is not particularly limited and may be a plate shape, a foil shape, a film shape, a powder shape, or a block shape, for example. Examples of the member to be etched include the above-described semiconductor substrate.

### [Etching Object]

The etching object may be formed of only materials containing silicon, may have a portion formed of only materials containing silicon and a portion formed of other materials, or may be formed of a mixture of materials containing silicon and other materials. Examples of the materials containing silicon include silicon oxide, silicon nitride, polysilicon, and silicon germanium (SiGe), for example. The materials containing silicon may be used alone or in combination of two or more types thereof.

Examples of silicon oxide include silicon dioxide (SiO₂). Silicon nitride refers to a compound having silicon and nitrogen in an optional ratio, and includes Si₃N₄, for example. The purity of silicon nitride is not particularly limited, and is preferably 30% by mass or more, more preferably 60% by mass or more, and still more preferably 90% by mass or more.

The shape of the etching object is not particularly limited and may be a plate shape, a foil shape, a film shape, a powder shape, or a block shape, for example. The etching object may or may not have shapes, such as patterns or holes, formed therein.

### [Non-Etching Object]

The non-etching object does not substantially react with the above-described etching compounds or extremely slowly reacts with the above-described etching compounds. Therefore, even when etching is performed by the etching method according to this embodiment, the etching hardly progresses. The non-etching object is not particularly limited insofar as it has the above-described properties. Examples include a photoresist, amorphous carbon, titanium nitride, metals, such as copper, nickel, and cobalt, and oxides and nitrides of these metals. Among the above, a photoresist and amorphous carbon are more preferable from the viewpoint of ease of handling properties and availability.

The non-etching object is usable as a resist or a mask for suppressing the etching of the etching object by the etching gas. Thus, the etching method according to this embodiment can be utilized for a method including processing the etching object into a predetermined shape (e.g., processing the etching object in a film shape possessed by the member to be etched to have a predetermined film thickness), for example, utilizing the patterned non-etching object as the resist or the mask, and therefore is suitably usable for the manufacture of semiconductor elements. The non-etching object is hardly etched, and therefore etching of a portion that should not be essentially etched of a semiconductor element can be suppressed and the loss of the characteristics of a semiconductor element by etching can be prevented.

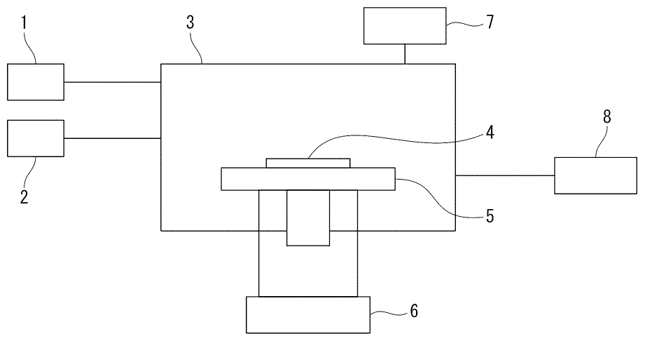

Next, one example of the configuration of an etching device capable of implementing the etching method according to this embodiment and one example of an etching method using the etching device are described with reference to FIG. 1. The etching device in FIG. 1 is a plasma etching device for performing etching using a plasma. First, the etching device in FIG. 1 is described.

The etching device in FIG. 1 includes a chamber 3 inside which etching is performed, a plasma generating device (not illustrated) generating a plasma into the chamber 3, a stage 5 supporting a member to be etched 4 that is etched inside the chamber 3, a cooling section 6 cooling the member to be etched 4 through the stage 5, a thermometer (not illustrated) measuring the temperature of the member to be etched 4, a vacuum pump 8 reducing the pressure inside the chamber 3, and a pressure gauge 7 measuring the pressure inside the chamber 3.

The type of a plasma generating mechanism of the plasma generating device is not particularly limited, and may be one applying a high-frequency voltage to parallel plates or one passing a high-frequency current through a coil. When a high-frequency voltage is applied to the member to be etched 4 in a plasma, a negative voltage is applied to the member to be etched 4, and positive ions are incident on the member to be etched 4 at high speed and perpendicularly, making anisotropic etching possible.

In the etching device in FIG. 1, the stage 5 and a high frequency power supply of the plasma generating device are connected to each other, and a high frequency voltage can be applied to the stage 5.

The etching device in FIG. 1 includes an etching gas supply section supplying an etching gas to the chamber 3.

The etching gas supply section has an etching compound gas supply section 1 supplying an etching compound gas, a dilution gas supply section 2 supplying dilution gas, a pipe connecting the etching compound gas supply section 1 and the chamber 3, and a pipe connecting the dilution gas supply section 2 and the chamber 3. A facility supplying additive gas may also be provided (not illustrated) in a form similar to that of the dilution gas supply section 2. The gas, such as the etching gas, supplied into the chamber 3 can be discharged out of the chamber 3 through an exhaust pipe, which is not illustrated.

When the etching compound gas is used as the etching gas, the etching compound gas may be supplied to the chamber 3 through a pipe by feeding out the etching compound gas from the etching compound gas supply section 1 after the inside of the chamber 3 is depressurized with the vacuum pump 8.

When a mixture of the etching compound gas and the dilution gas, such as inert gas, is used as the etching gas, the etching compound gas may be fed out from the etching compound gas supply section 1 and the dilution gas may be fed out from the dilution gas supply section 2 after the inside of the chamber 3 is depressurized with the vacuum pump 8. Thus, the etching compound gas and the dilution gas are mixed in the chamber 3 to form the etching gas.

The etching method according to this embodiment can be implemented using a common plasma etching device used in a semiconductor element manufacturing process, such as the etching device in FIG. 1, and the configurations of usable etching devices are not limited.

For example, the configuration of a temperature control mechanism of the chamber 3 may be a configuration in which the stage 5 is cooled from the outside of the chamber 3 with an external cooling section 6 as in the etching device in FIG. 1 or may be a configuration in which a cooling section cooling the stage 5 is provided directly on the stage 5 because the temperature of the member to be etched 4 only needs to be controlled to an optional temperature.

### EXAMPLES

The present invention is more specifically described with reference to Examples and Comparative Examples below. Etching compound gases containing various concentrations of metal impurities were prepared. Preparation examples of the etching compound gases are described below.

### Preparation Example 1

Three 1 L volume manganese steel cylinders (sealable cylindrical containers) were prepared. The cylinders are referred to as a cylinder A, a cylinder B, and a cylinder C in order. The cylinder A was filled with 300 g of tetrafluoromethane (boiling point at normal pressure: −128° C.). The tetrafluoromethane was liquefied by being cooled to −125° C., forming a liquid phase part and a gas phase part in an almost 100 kPa state. The cylinders B, C were cooled to −196° C. after the inside was depressurized to 1 kPa or less with a vacuum pump.

200 g of tetrafluoromethane gas was extracted from an upper outlet, where the gas phase part is present, of the cylinder A, and transferred to the cylinder B in the depressurized state. 100 g of the tetrafluoromethane remaining in the cylinder A is set as Sample 1-1. Then, the tetrafluoromethane gas remaining in the cylinder A was extracted from the upper outlet, and the concentrations of various metals were measured with an inductively coupled plasma mass spectrometer according to the following method.

More specifically, while the tetrafluoromethane in a liquid phase in the cylinder A was being vaporized at 20° C., the tetrafluoromethane gas was extracted from the gas phase part, and distributed and brought into contact (bubbled) with 100 g of an aqueous nitric acid solution having a concentration of 1 mol/L at a flow rate of 100 mL/min for absorption of the metal impurities. The mass of the aqueous nitric acid solution having a concentration of 1 mol/L after the tetrafluoromethane gas was distributed was 80 g (M1). A mass difference in the cylinder A before and after the distribution of the tetrafluoromethane gas was 50 g (M2).

10 g (M3) of the aqueous nitric acid solution having a concentration of 1 mol/L was collected and diluted to 100 mL (V) with ultrapure water using a female flask. The concentrations of various metals in the aqueous solution thus prepared were measured with an inductively coupled plasma mass spectrometer, and the concentrations of the metals (C) in the tetrafluoromethane were calculated using a measured value (c1) and the following equation. The results are shown in Table 1.

$$C = \{ ( c 1 \times V ) \times ( M 1 / M 3 ) \} / M 2$$

TABLE 1

| | Concentrations of | | | Concentrations of | | | Concentrations of chromium, manganese, iron, | | | | | | | | | |
|---|---|---|---|---|---|---|---|---|---|---|---|---|---|---|---|---|
| | alkaline metals | | | alkaline earth metals | | | cobalt, nickel, copper, zinc, aluminum, tin | | | | | | | | | |
| | Li | Na | K | Mg | Ca | Total | Cr | Mn | Fe | Co | Ni | Cu | Zn | Al | Sn | Total |
| Sample 1-1 | 983 | 1205 | 1311 | 1004 | 1225 | 5828 | 1441 | 1286 | 1835 | 1637 | 1772 | 1635 | 1588 | 1535 | 1148 | 13877 |
| Sample 1-2 | 174 | 205 | 226 | 187 | 198 | 990 | 272 | 215 | 339 | 307 | 321 | 294 | 275 | 301 | 229 | 2553 |
| Sample 1-3 | 12 | 22 | 25 | 15 | 18 | 92 | 36 | 27 | 45 | 40 | 48 | 39 | 38 | 41 | 28 | 342 |

*) Unit of numerical values is ppb by mass.

Next, the temperature of the cylinder B was raised to −125° C., forming a liquid phase part and a gas phase part. 100 g of the tetrafluoromethane gas was extracted from an upper outlet, where the gas phase part was present, of the cylinder B and transferred to the cylinder C in the depressurized state. 100 g of the tetrafluoromethane remaining in the cylinder B is set as Sample 1-2. Then, the tetrafluoromethane gas remaining in the cylinder B was extracted from the upper outlet, and the concentrations of various metals were measured with an inductively coupled plasma mass spectrometer. The results are shown in Table 1.

Further, 100 g of the tetrafluoromethane in the cylinder C is set as Sample 1-3. The tetrafluoromethane gas was extracted from an upper outlet, where the gas phase part was present, of the cylinder C, and the concentrations of various metals were measured with an inductively coupled plasma mass spectrometer. The results are shown in Table 1.

### Preparation Example 2

Samples 2-1, 2-2, 2-3 were prepared by performing the same operation as that in Preparation example 1, except that methane (boiling point at normal pressure: −162° C.) was used as the etching compound and the liquefaction temperature was set to −153° C. Then, the concentrations of various metals in each sample were measured with an inductively coupled plasma mass spectrometer in the same manner as in Preparation example 1 described above. The results are shown in Table 2.

TABLE 2

| | Concentrations of | | | Concentrations of | | | Concentrations of chromium, manganese, iron, | | | | | | | | | |
|---|---|---|---|---|---|---|---|---|---|---|---|---|---|---|---|---|
| | alkaline metals | | | alkaline earth metals | | | cobalt, nickel, copper, zinc, aluminum, tin | | | | | | | | | |
| | Li | Na | K | Mg | Ca | Total | Cr | Mn | Fe | Co | Ni | Cu | Zn | Al | Sn | Total |
| Sample 2-1 | 953 | 1494 | 1355 | 1136 | 1039 | 5977 | 1522 | 1356 | 1754 | 1788 | 1811 | 1678 | 1622 | 1615 | 1200 | 14346 |
| Sample 2-2 | 145 | 249 | 212 | 183 | 161 | 950 | 257 | 225 | 293 | 288 | 308 | 274 | 263 | 268 | 199 | 2375 |
| Sample 2-3 | 11 | 24 | 21 | 13 | 18 | 87 | 37 | 34 | 46 | 44 | 44 | 34 | 37 | 39 | 23 | 338 |

*) Unit of numerical values is ppb by mass.

### Preparation Example 3

Samples 3-1,3-2, 3-3 were prepared by performing the same operation as that in Preparation example 1, except that oxygen gas (boiling point at normal pressure: −183° C.) was used as the etching compound and the liquefaction temperature was set to −153° C. Then, the concentrations of various metals in each sample were measured with an inductively coupled plasma mass spectrometer in the same manner as in Preparation example 1 described above. The results are shown in Table 3.

TABLE 3

| | Concentrations of | | | Concentrations of | | | Concentrations of chromium, manganese, iron, | | | | | | | | | |
|---|---|---|---|---|---|---|---|---|---|---|---|---|---|---|---|---|
| | alkaline metals | | | alkaline earth metals | | | cobalt, nickel, copper, zinc, aluminum, tin | | | | | | | | | |
| | Li | Na | K | Mg | Ca | Total | Cr | Mn | Fe | Co | Ni | Cu | Zn | Al | Sn | Total |
| Sample 3-1 | 1025 | 1321 | 1333 | 984 | 991 | 5654 | 1511 | 1341 | 1653 | 1672 | 1733 | 1544 | 1601 | 1588 | 1203 | 13846 |
| Sample 3-2 | 173 | 227 | 221 | 162 | 161 | 944 | 248 | 215 | 266 | 267 | 288 | 243 | 268 | 257 | 199 | 2251 |
| Sample 3-3 | 18 | 21 | 25 | 16 | 15 | 95 | 32 | 29 | 36 | 34 | 40 | 33 | 37 | 35 | 24 | 300 |

*) Unit of numerical values is ppb by mass.

### Preparation Example 4

Samples 4-1,4-2, 4-3 were prepared by performing the same operation as that in Preparation example 1, except that difluoromethane (boiling point at normal pressure: −52° C.) was used as the etching compound and the liquefaction temperature was set to −50° C. Then, the concentrations of various metals in each sample were measured with an inductively coupled plasma mass spectrometer in the same manner as in Preparation example 1 described above. The results are shown in Table 4.

TABLE 4

| | Concentrations of | | | Concentrations of | | | Concentrations of chromium, manganese, iron, | | | | | | | | | |
|---|---|---|---|---|---|---|---|---|---|---|---|---|---|---|---|---|
| | alkaline metals | | | alkaline earth metals | | | cobalt, nickel, copper, zinc, aluminum, tin | | | | | | | | | |
| | Li | Na | K | Mg | Ca | Total | Cr | Mn | Fe | Co | Ni | Cu | Zr | Al | Sn | Total |
| Sample 4-1 | 1201 | 1422 | 1391 | 1003 | 1043 | 6060 | 1665 | 1403 | 1788 | 1705 | 1738 | 1632 | 1612 | 1684 | 1122 | 14349 |
| Sample 4-2 | 199 | 212 | 208 | 143 | 155 | 917 | 278 | 238 | 298 | 282 | 287 | 272 | 267 | 270 | 177 | 2369 |
| Sample 4-3 | 18 | 17 | 19 | 13 | 14 | 81 | 38 | 34 | 45 | 42 | 41 | 36 | 37 | 35 | 26 | 334 |

*) Unit of numerical values is ppb by mass.

### Preparation Example 5

Samples 5-1, 5-2, 5-3 were prepared by performing the same operation as that in Preparation example 1, except that carbonyl fluoride (boiling point at normal pressure: −85° C.) was used as the etching compound and the liquefaction temperature was set to −78° C. Then, the concentrations of various metals in each sample were measured with an inductively coupled plasma mass spectrometer in the same manner as in Preparation example 1 described above. The results are shown in Table 5.

TABLE 5

| | Concentrations of | | | Concentrations of | | | Concentrations of chromium, manganese, iron, | | | | | | | | | |
|---|---|---|---|---|---|---|---|---|---|---|---|---|---|---|---|---|
| | alkaline metals | | | alkaline earth metals | | | cobalt, nickel, copper, zinc, aluminum, tin | | | | | | | | | |
| | Li | Na | K | Mg | Ca | Total | Cr | Mn | Fe | Cc | Ni | Cu | Zn | Al | Sn | Total |
| Sample 5-1 | 1180 | 1225 | 1209 | 1018 | 984 | 5616 | 1522 | 1417 | 1603 | 1583 | 1591 | 1512 | 1567 | 1539 | 1233 | 13567 |
| Sample 5-2 | 171 | 175 | 177 | 148 | 147 | 818 | 214 | 204 | 229 | 221 | 223 | 215 | 222 | 218 | 176 | 1922 |
| Sample 5-3 | 15 | 16 | 15 | 14 | 12 | 72 | 31 | 29 | 37 | 30 | 31 | 29 | 32 | 31 | 24 | 274 |

*) Unit of numerical values is ppb by mass.

### Preparation Example 6

Samples 6-1, 6-2, 6-3 were prepared by performing the same operation as that in Preparation example 1, except that dimethyl ether (boiling point at normal pressure: −24° C.) was used as the etching compound and the liquefaction temperature was set to −20° C. Then, the concentrations of various metals in each sample were measured with an inductively coupled plasma mass spectrometer in the same manner as in Preparation example 1 described above. The results are shown in Table 6.

TABLE 6

| | Concentrations of | | | Concentrations of | | | Concentrations of chromium, manganese, iron, | | | | | | | | | |
|---|---|---|---|---|---|---|---|---|---|---|---|---|---|---|---|---|
| | alkaline metals | | | alkaline earth metals | | | cobalt, nickel, copper, zinc, aluminum, tin | | | | | | | | | |
| | Li | Na | K | Mg | Ca | Total | Cr | Mn | Fe | Co | Ni | Cu | Zn | Al | Sn | Total |
| Sample 6-1 | 1277 | 1402 | 1388 | 1317 | 1301 | 6685 | 1821 | 1743 | 1888 | 1739 | 1803 | 1758 | 1822 | 1792 | 1333 | 15699 |
| Sample 6-2 | 181 | 199 | 192 | 182 | 181 | 935 | 260 | 249 | 270 | 244 | 256 | 251 | 263 | 256 | 194 | 2243 |
| Sample 6-3 | 17 | 18 | 18 | 15 | 14 | 82 | 38 | 35 | 37 | 36 | 37 | 38 | 37 | 36 | 24 | 318 |

*) Unit of numerical values is ppb by mass.

### Example 1

On the surface of a semiconductor wafer, a 1000 nm thick silicon oxide film and a 1000 nm thick silicon nitride film each were formed to be exposed to the surface without being stacked, and the resultant semiconductor wafer was set as a test piece. Then, the test piece was etched using an etching gas.

As the etching device, an ICP etching device RIE-230iP manufactured by Samco Inc., was used. Specifically, the etching gas was prepared by independently introducing each of the tetrafluoromethane of Sample 1-3 at a flow rate of 10 mL/min, the methane of Sample 2-3 at a flow rate of 5 mL/min, the oxygen gas of Sample 3-3 at a flow rate of 5 mL/min, and argon at a flow rate of 30 mL/min into a chamber and mixing them in the chamber. Then, the etching gas in the chamber was partially taken out, and the concentrations of various metals in the etching gas were measured with an inductively coupled plasma mass spectrometer. The results are shown in Table 7.

Next, a high-frequency voltage was applied at 500 W to convert the etching gas into a plasma in the chamber. Then, the test piece in the chamber was etched under etching conditions of a pressure of 3 Pa, a temperature of the test piece of −50° C., and a bias power of 100 W.

When the etching was completed, the temperature of the test piece was set to 20° C. and argon was introduced into the chamber at a flow rate of 30 mL/min to purge the surface of the test piece. Thereafter, the test piece was taken out from the chamber, and the number of particles present on the surface of each of the silicon oxide film and the silicon nitride film was measured. The number of the particles was measured using a Surfscan SP1 manufactured by KLA Tencor. The results are shown in Table 7. As shown in Table 7, the number of the particles is 0.1 particles/cm² or less, and therefore the generation of the particles by etching is suppressed.

TABLE 7

| | | | | | | | | | | | | | | | | Number of particles | |
|---|---|---|---|---|---|---|---|---|---|---|---|---|---|---|---|---|---|
| | | | | | | | | | | | | | | | | (particles/cm²) | |
| | | | | | | | | | | | | | | | | Silicon | Silicon |
| | Concentrations of metals (ppb by mass) | | | | | | | | | | | | | | | oxide | nitride |
| | Li | Na | K | Mg | Ca | Cr | Mn | Fe | Co | Ni | Cu | Zn | Al | Sn | Total | film | film |
| Ex. 1 | 5 | 9 | 10 | 6 | 7 | 14 | 12 | 17 | 16 | 18 | 15 | 15 | 16 | 10 | 169 | 0.02 | 0.01 |
| Ex. 2 | 38 | 46 | 50 | 40 | 43 | 61 | 49 | 76 | 69 | 73 | 66 | 62 | 68 | 51 | 791 | 0.08 | 0.09 |
| Comp. Ex. 1 | 200 | 246 | 267 | 204 | 248 | 295 | 264 | 375 | 335 | 363 | 334 | 325 | 314 | 234 | 4003 | 1.3 | 1.1 |

### Example 2

The test piece was etched by performing the same operation as that in Example 1, except that the tetrafluoromethane of Sample 1-2 was used in place of the tetrafluoromethane of Sample 1-3. The measurement results of the concentrations of the metals and the measurement results of the number of particles are shown in Table 7. As shown in Table 7, the number of the particles is 0.1 particles/cm² or less, and therefore the generation of the particles by etching is suppressed.

### Comparative Example 1

The test piece was etched by performing the same operation as that in Example 1, except that the tetrafluoromethane of Sample 1-1 was used in place of the tetrafluoromethane of Sample 1-3. The measurement results of the concentrations of the metals and the measurement results of the number of particles are shown in Table 7. As shown in Table 7, the number of the particles is more than 0.5 particles/cm², and therefore the generation of the particles by etching is not suppressed.

### Example 3

The test piece was etched by performing the same operation as that in Example 1, except that an etching gas was prepared by independently introducing each of the methane of Sample 2-3 at a flow rate of 10 mL/min, the tetrafluoromethane of Sample 1-3 at a flow rate of 5 mL/min, the oxygen gas of Sample 3-3 at a flow rate of 5 mL/min, and argon at a flow rate of 30 mL/min into a chamber and mixing them in the chamber.

When the etching was completed, the temperature of the test piece was set to 20° C. and argon was introduced into the chamber at a flow rate of 30 mL/min to purge the surface of the test piece. After the purge was completed, the test piece was taken out from the chamber, and the number of particles was measured in the same manner as in Example 1. Table 8 shows the measurement results of the concentrations of the metals and the measurement results of the number of particles.

As shown in Table 8, the number of the particles is 0.1 particles/cm² or less, and therefore the generation of the particles by etching is suppressed.

TABLE 8

| | | | | | | | | | | | | | | | | Number of particles | |
|---|---|---|---|---|---|---|---|---|---|---|---|---|---|---|---|---|---|
| | | | | | | | | | | | | | | | | (particles/cm²) | |
| | | | | | | | | | | | | | | | | Silicon | Silicon |
| | Concentrations of metals (ppb by mass) | | | | | | | | | | | | | | | oxide | nitride |
| | Li | Na | K | Mg | Ca | Cr | Mn | Fe | Co | Ni | Cu | Zn | Al | Sn | Total | film | film |
| Ex. 3 | 5 | 9 | 9 | 6 | 7 | 14 | 12 | 17 | 16 | 18 | 14 | 15 | 15 | 10 | 168 | 0.02 | 0.02 |
| Ex. 4 | 32 | 54 | 47 | 40 | 36 | 58 | 51 | 67 | 65 | 70 | 62 | 60 | 61 | 45 | 748 | 0.07 | 0.08 |
| Comp. Ex. 2 | 194 | 303 | 276 | 230 | 211 | 311 | 277 | 359 | 365 | 371 | 343 | 332 | 331 | 245 | 4148 | 1.1 | 1.2 |

### Example 4

The test piece was etched and purged by performing the same operation as that in Example 3, except that the methane of Sample 2-2 was used in place of the methane of Sample 2-3. Table 8 shows the measurement results of the concentrations of the metals and the measurement results of the number of particles. As shown in Table 8, the number of the particles is 0.1 particles/cm² or less, and therefore the generation of the particles by etching is suppressed.

### Comparative Example 2

The test piece was etched and purged by performing the same operation as that in Example 3, except that the methane of Sample 2-1 was used in place of the methane of Sample 2-3. Table 8 shows the measurement results of the concentrations of the metals and the measurement results of the number of particles. As shown in Table 8, the number of the particles is more than 0.5 particles/cm², and therefore the generation of the particles by etching is not suppressed.

### Example 5

The test piece was etched and purged by performing the same operation as that in Example 3, except that an etching gas was prepared by independently introducing each of the oxygen gas of Sample 3-3 at a flow rate of 10 mL/min, the difluoromethane of Sample 4-3 at a flow rate of 10 mL/min, and argon at a flow rate of 30 mL/min into a chamber and mixing them in the chamber. Table 9 shows the measurement results of the concentrations of the metals and the measurement results of the number of particles. As shown in Table 9, the number of the particles is 0.1 particles/cm² or less, and therefore the generation of the particles by etching is suppressed.

TABLE 9

| | | | | | | | | | | | | | | | | Number of particles | |
|---|---|---|---|---|---|---|---|---|---|---|---|---|---|---|---|---|---|
| | | | | | | | | | | | | | | | | (particles/cm²) | |
| | | | | | | | | | | | | | | | | Silicon | Silicon |
| | Concentrations of metals (ppb by mass) | | | | | | | | | | | | | | | oxide | nitride |
| | Li | Na | K | Mg | Ca | Cr | Mn | Fe | Cc | Ni | Cu | Zn | Al | Sn | Total | film | film |
| Ex. 5 | 7 | 8 | 9 | 6 | 6 | 14 | 13 | 16 | 15 | 16 | 14 | 15 | 14 | 10 | 162 | 0.03 | 0.02 |
| Ex. 6 | 38 | 49 | 48 | 35 | 35 | 57 | 50 | 62 | 62 | 66 | 56 | 61 | 58 | 45 | 722 | 0.1 | 0.09 |
| Ex. 7 | 43 | 47 | 47 | 32 | 34 | 62 | 53 | 67 | 63 | 65 | 61 | 61 | 61 | 40 | 736 | 0.09 | 0.08 |
| Comp. Ex. 3 | 219 | 268 | 270 | 199 | 201 | 310 | 275 | 340 | 343 | 355 | 316 | 328 | 335 | 246 | 4004 | 1.5 | 1.2 |
| Comp. Ex. 4 | 244 | 289 | 283 | 204 | 212 | 339 | 286 | 365 | 348 | 356 | 333 | 330 | 344 | 229 | 4161 | 1.7 | 1.9 |

### Example 6

The test piece was etched and purged by performing the same operation as that in Example 5, except that the oxygen gas of Sample 3-2 was used in place of the oxygen gas of Sample 3-3. Table 9 shows the measurement results of the concentrations of the metals and the measurement results of the number of particles. As shown in Table 9, the number of the particles is 0.1 particles/cm² or less, and therefore the generation of the particles by etching is suppressed.

### Example 7

The test piece was etched and purged by performing the same operation as that in Example 5, except that the difluoromethane of Sample 4-2 was used in place of the difluoromethane of Sample 4-3. Table 9 shows the measurement results of the concentrations of the metals and the measurement results of the number of particles. As shown in Table 9, the number of the particles is 0.1 particles/cm² or less, and therefore the generation of the particles by etching is suppressed.

### Comparative Example 3

The test piece was etched and purged by performing the same operation as that in Example 5, except that the oxygen gas of Sample 3-1 was used in place of the oxygen gas of Sample 3-3. Table 9 shows the measurement results of the concentrations of the metals and the measurement results of the number of particles. As shown in Table 9, the number of the particles is more than 0.5 particles/cm², and therefore the generation of the particles by etching is not suppressed.

### Comparative Example 4

The test piece was etched and purged by performing the same operation as that in Example 5, except that the difluoromethane of Sample 4-1 was used in place of the difluoromethane of Sample 4-3. Table 9 shows the measurement results of the concentrations of the metals and the measurement results of the number of particles. As shown in Table 9, the number of the particles is more than 0.5 particles/cm², and therefore the generation of the particles by etching is not suppressed.

### Example 8

The test piece was etched and purged by performing the same operation as that in Example 3, except that an etching gas was prepared by independently introducing each of the carbonyl fluoride of Sample 5-3 at a flow rate of 10 mL/min, the methane of Sample 2-3 at a flow rate of 10 mL/min, and argon at a flow rate of 30 mL/min into a chamber and mixing them in the chamber. Table 10 shows the measurement results of the concentrations of the metals and the measurement results of the number of particles. As shown in Table 10, the number of the particles is 0.1 particles/cm² or less, and therefore the generation of the particles by etching is suppressed.

TABLE 10

| | | | | | | | | | | | | | | | | Number of particles | |
|---|---|---|---|---|---|---|---|---|---|---|---|---|---|---|---|---|---|
| | | | | | | | | | | | | | | | | (particles/cm²) | |
| | | | | | | | | | | | | | | | | Silicon | Silicon |
| | Concentrations of metals (ppb by mass) | | | | | | | | | | | | | | | oxide | nitride |
| | Li | Na | K | Mg | Ca | Cr | Mn | Fe | Co | Ni | Cu | Zr | Al | Sn | Total | film | film |
| Ex. 8 | 5 | 8 | 7 | 5 | 6 | 14 | 13 | 17 | 15 | 15 | 13 | 14 | 14 | 9 | 154 | 0.03 | 0.02 |
| Ex. 9 | 36 | 40 | 40 | 32 | 33 | 50 | 48 | 55 | 53 | 53 | 50 | 52 | 51 | 40 | 633 | 0.09 | 0.09 |
| Comp. Ex. 5 | 238 | 250 | 246 | 241 | 230 | 312 | 295 | 330 | 325 | 327 | 320 | 321 | 326 | 251 | 4012 | 1.8 | 1.5 |

### Example 9

The test piece was etched and purged by performing the same operation as that in Example 8, except that the carbonyl fluoride of Sample 5-2 was used in place of the carbonyl fluoride of Sample 5-3. Table 10 shows the measurement results of the concentrations of the metals and the measurement results of the number of particles. As shown in Table 10, the number of the particles is 0.1 particles/cm² or less, and therefore the generation of the particles by etching is suppressed.

### Comparative Example 5

The test piece was etched and purged by performing the same operation as that in Example 8, except that the carbonyl fluoride of Sample 5-1 was used in place of the carbonyl fluoride of Sample 5-3. Table 10 shows the measurement results of the concentrations of the metals and the measurement results of the number of particles. As shown in Table 10, the number of the particles is more than 0.5 particles/cm², and therefore the generation of the particles by etching is not suppressed.

### Example 10

The test piece was etched and purged by performing the same operation as that in Example 3, except that an etching gas was prepared by independently introducing each of the dimethyl ether of Sample 6-3 at a flow rate of 10 mL/min, the tetrafluoromethane of Sample 1-3 at a flow rate of 10 mL/min, and argon at a flow rate of 30 mL/min into a chamber and mixing them in the chamber. Table 11 shows the measurement results of the concentrations of the metals and the measurement results of the number of particles. As shown in Table 11, the number of the particles is 0.1 particles/cm² or less, and therefore the generation of the particles by etching is suppressed.

TABLE 11

| | | | | | | | | | | | | | | | | Number of particles | |
|---|---|---|---|---|---|---|---|---|---|---|---|---|---|---|---|---|---|
| | | | | | | | | | | | | | | | | (particles/cm²) | |
| | | | | | | | | | | | | | | | | Silicon | Silicon |
| | Concentrations of metals (ppb by mass) | | | | | | | | | | | | | | | oxide | nitride |
| | Li | Na | K | Mg | Ca | Cr | Mr | Fe | Co | Ni | Cu | Zn | Al | Sn | Total | film | film |
| Ex. 10 | 6 | 8 | 9 | 6 | 6 | 15 | 12 | 16 | 15 | 17 | 15 | 15 | 15 | 10 | 167 | 0.02 | 0.02 |
| Ex. 11 | 39 | 44 | 43 | 39 | 40 | 59 | 55 | 63 | 57 | 61 | 58 | 60 | 59 | 44 | 722 | 0.08 | 0.09 |
| Comp. Ex. 6 | 258 | 285 | 283 | 266 | 264 | 371 | 354 | 387 | 356 | 370 | 359 | 372 | 367 | 272 | 4564 | 1.3 | 1.4 |

### Example 11

The test piece was etched and purged by performing the same operation as that in Example 10, except that the dimethyl ether of Sample 6-2 was used in place of the dimethyl ether of Sample 6-3. Table 11 shows the measurement results of the concentrations of the metals and the measurement results of the number of particles. As shown in Table 11, the number of the particles is 0.1 particles/cm² or less, and therefore the generation of the particles by etching is suppressed.

### Comparative Example 6

The test piece was etched and purged by performing the same operation as that in Example 10, except that the dimethyl ether of Sample 6-1 was used in place of the dimethyl ether of Sample 6-3. Table 11 shows the measurement results of the concentrations of the metals and the measurement results of the number of particles. As shown in Table 11, the number of the particles is more than 0.5 particles/cm², and therefore the generation of the particles by etching is not suppressed.

### Example 12

The test piece was etched by performing the same operation as that in Example 1, except that the temperature of the test piece was set to −5° C. The number of particles present on the surface of the silicon oxide film was 0.04 particles/cm² and the number of particles present on the surface of the silicon nitride film was 0.03 particles/cm², and the generation of particles by etching was suppressed.

### Comparative Example 7

The test piece was etched by performing the same operation as that in Comparative Example 1, except that the temperature of the test piece was set to −5° C. The number of particles present on the surface of the silicon oxide film was 1.4 particles/cm² and the number of particles present on the surface of the silicon nitride film was 1.1 particles/cm², and the generation of particles by etching was not suppressed.

### Reference Example 1

The test piece was etched by performing the same operation as that in Example 1, except that the temperature of the test piece was set to 25° C. The number of particles present on the surface of the silicon oxide film was 0.02 particles/cm² and the number of particles present on the surface of the silicon nitride film was 0.03 particles/cm², and the generation of particles by etching was suppressed.

### Reference Example 2

The test piece was etched by performing the same operation as that in Comparative Example 1, except that the temperature of the test piece was set to 25° C. The number of particles present on the surface of the silicon oxide film was 0.07 particles/cm² and the number of particles present on the surface of the silicon nitride film was 0.05 particles/cm², and the generation of particles by etching was suppressed.

Reference Signs List

| | |
|---|---|
| 1 | etching compound gas supply section |
| 2 | dilution gas supply section |
| 3 | chamber |
| 4 | member to be etched |
| 5 | stage |
| 6 | cooling section |
| 7 | pressure gauge |
| 8 | vacuum pump |

1. An etching method comprising:
an etching step of setting a temperature of a member to be etched having an etching object containing silicon to 0° C. or less, bringing an etching gas containing an etching compound into contact with the member to be etched, and etching the etching object,
the etching compound being a compound having at least one type of atom among a fluorine atom, a hydrogen atom, and an oxygen atom in a molecule, wherein
the etching gas contains or does not contain metal impurities having at least one type of metal, and, when the etching gas contains the metal impurities, a total concentration of all types of the contained metals is 4000 ppb by mass or less.

2. The etching method according to claim 1, wherein the total concentration of all types of the contained metals is 10 ppb by mass or more and 4000 ppb by mass or less.

3. The etching method according to claim 1, wherein the metal impurities have at least one type among alkaline metal, alkaline earth metal, chromium, manganese, iron, cobalt, nickel, copper, zinc, aluminum, and tin.

4. The etching method according to claim 3, wherein the alkaline metal is at least one type among lithium, sodium, and potassium, and the alkaline earth metal is at least one type of magnesium and calcium.

5. The etching method according to claim 1, wherein a concentration of each of all types of the contained metals is 1 ppb by mass or more.

6. The etching method according to claim 1, wherein the etching compound is at least one type among a compound having a fluorine atom in a molecule and not having a hydrogen atom and an oxygen atom in the molecule, a compound having a hydrogen atom in a molecule and not having a fluorine atom and an oxygen atom in the molecule, a compound having an oxygen atom in a molecule and not having a fluorine atom and a hydrogen atom in the molecule, a compound having a fluorine atom and a hydrogen atom in a molecule and not having an oxygen atom in the molecule, a compound having a fluorine atom and an oxygen atom in a molecule and not having a hydrogen atom in the molecule, and a compound having a hydrogen atom and an oxygen atom in a molecule and not having a fluorine atom in the molecule.

7. The etching method according to claim 6, wherein the compound having a fluorine atom in the molecule and not having a hydrogen atom and an oxygen atom in the molecule is at least one type among sulfur hexafluoride, nitrogen trifluoride, chlorine trifluoride, iodine heptafluoride, bromine pentafluoride, phosphorus trifluoride, trifluoroiodomethane, fluorine gas, chain saturated perfluorocarbons having 1 or more and 3 or less carbon atoms, unsaturated perfluorocarbons having 2 or more and 6 or less carbon atoms, cyclic perfluorocarbons having 3 or more and 6 or less carbon atoms, and halons having 1 or more and 3 or less carbon atoms.

8. The etching method according to claim 6, wherein the compound having a hydrogen atom in the molecule and not having a fluorine atom and an oxygen atom in the molecule is at least one type among bromomethane, dibromomethane, hydrogen gas, hydrogen sulfide, hydrogen chloride, hydrogen bromide, ammonia, alkanes having 1 or more and 3 or less carbon atoms, alkenes having 2 or more and 4 or less carbon atoms, and cyclic alkanes having 3 or more and 6 or less carbon atoms.

9. The etching method according to claim 6, wherein the compound having an oxygen atom in the molecule and not having a fluorine atom and a hydrogen atom in the molecule is at least one type among oxygen gas, carbon monoxide, carbon dioxide, carbonyl sulfide, and sulfur dioxide.

10. The etching method according to claim 6, wherein the compound having a fluorine atom and a hydrogen atom in the molecule and not have an oxygen atom in the molecule is at least one type among chain saturated hydrofluorocarbons having 1 or more and 4 or less carbon atoms, unsaturated hydrofluorocarbons having 2 or more and 6 or less carbon atoms, and cyclic hydrofluorocarbons having 3 or more and 6 or less carbon atoms, and hydrogen fluoride.

11. The etching method according to claim 6, wherein the compound having a fluorine atom and an oxygen atom in the molecule and not having a hydrogen atom in the molecule is at least one type among carbonyl fluoride, oxygen difluoride, trifluoromethyl hypofluoride, perfluoroethers having 2 or more and 4 or less carbon atoms, and perfluoroketones having 3 or more and 5 or less carbon atoms.

12. The etching method according to claim 6, wherein the compound having a hydrogen atom and an oxygen atom in the molecule and not having a fluorine atom in the molecule is at least one type among water, alcohols having 1 or more and 3 or less carbon atoms, ethers having 2 or more and 4 or less carbon atoms, and ketones having 3 or more and 5 or less carbon atoms.

13. The etching method according to claim 2, wherein the metal impurities have at least one type among alkaline metal, alkaline earth metal, chromium, manganese, iron, cobalt, nickel, copper, zinc, aluminum, and tin.

14. The etching method according to claim 2, wherein a concentration of each of all types of the contained metals is 1 ppb by mass or more.

15. The etching method according to claim 3, wherein a concentration of each of all types of the contained metals is 1 ppb by mass or more.

16. The etching method according to claim 4, wherein a concentration of each of all types of the contained metals is 1 ppb by mass or more.

17. The etching method according to claim 2, wherein the etching compound is at least one type among a compound having a fluorine atom in a molecule and not having a hydrogen atom and an oxygen atom in the molecule, a compound having a hydrogen atom in a molecule and not having a fluorine atom and an oxygen atom in the molecule, a compound having an oxygen atom in a molecule and not having a fluorine atom and a hydrogen atom in the molecule, a compound having a fluorine atom and a hydrogen atom in a molecule and not having an oxygen atom in the molecule, a compound having a fluorine atom and an oxygen atom in a molecule and not having a hydrogen atom in the molecule, and a compound having a hydrogen atom and an oxygen atom in a molecule and not having a fluorine atom in the molecule.

18. The etching method according to claim 3, wherein the etching compound is at least one type among a compound having a fluorine atom in a molecule and not having a hydrogen atom and an oxygen atom in the molecule, a compound having a hydrogen atom in a molecule and not having a fluorine atom and an oxygen atom in the molecule, a compound having an oxygen atom in a molecule and not having a fluorine atom and a hydrogen atom in the molecule, a compound having a fluorine atom and a hydrogen atom in a molecule and not having an oxygen atom in the molecule, a compound having a fluorine atom and an oxygen atom in a molecule and not having a hydrogen atom in the molecule, and a compound having a hydrogen atom and an oxygen atom in a molecule and not having a fluorine atom in the molecule.

19. The etching method according to claim 4, wherein the etching compound is at least one type among a compound having a fluorine atom in a molecule and not having a hydrogen atom and an oxygen atom in the molecule, a compound having a hydrogen atom in a molecule and not having a fluorine atom and an oxygen atom in the molecule, a compound having an oxygen atom in a molecule and not having a fluorine atom and a hydrogen atom in the molecule, a compound having a fluorine atom and a hydrogen atom in a molecule and not having an oxygen atom in the molecule, a compound having a fluorine atom and an oxygen atom in a molecule and not having a hydrogen atom in the molecule, and a compound having a hydrogen atom and an oxygen atom in a molecule and not having a fluorine atom in the molecule.

20. The etching method according to claim 5, wherein the etching compound is at least one type among a compound having a fluorine atom in a molecule and not having a hydrogen atom and an oxygen atom in the molecule, a compound having a hydrogen atom in a molecule and not having a fluorine atom and an oxygen atom in the molecule, a compound having an oxygen atom in a molecule and not having a fluorine atom and a hydrogen atom in the molecule, a compound having a fluorine atom and a hydrogen atom in a molecule and not having an oxygen atom in the molecule, a compound having a fluorine atom and an oxygen atom in a molecule and not having a hydrogen atom in the molecule, and a compound having a hydrogen atom and an oxygen atom in a molecule and not having a fluorine atom in the molecule.
